(19) United States
(12) Patent Application Publication
(10) Pub. No.: US 2025/0391680 A1
(43) Pub. Date: Dec. 25, 2025

(54) Modular Substrate Processing Systems and Methods with Additional Processing Chamber Connectability

(71) Applicant: ASM IP Holding B.V., Almere (NL)

(72) Inventors: Masashi Nakano, Tokyo (JP); Taira Okabe, Kawasaki-shi (JP); Samer Banna, Phoenix, AZ (US); Senthil Arasu Subas Chandra Bose, Chandler, AZ (US); Senthil Sivaraman, Phoenix, AZ (US); Mandar Vijay Deshpande, Phoenix, AZ (US)

(21) Appl. No.: 19/311,335

(22) Filed: Aug. 27, 2025

Related U.S. Application Data
(63) Continuation-in-part of application No. 18/755,599, filed on Jun. 26, 2024.
(60) Provisional application No. 63/524,272, filed on Jun. 30, 2023.

(51) Int. Cl. H01L 21/67

(52) U.S. Cl. CPC H01L 21/67201; H01L 21/67167

(57) ABSTRACT

Substrate processing systems have expanded substrate processing capabilities. In some examples, this may be accomplished by providing an inboard substrate handling chamber (e.g., with six facets or side walls) and an outboard substrate handling chamber (e.g., with five facets or side walls). The inboard substrate handling chamber may be connected with additional substrate processing chambers. The inboard substrate handling chamber may be connected to the outboard substrate handling chamber by an additional outboard load-lock module. The inboard and outboard substrate handling chambers may be interchangeable. These features may enable a manufacturer to increase the number of substrate processing chambers in a substrate processing system or line without necessarily increasing the types of on-hand spare parts needed.

### CROSS-REFERENCE TO RELATED APPLICATION(S)

This Application is a continuation-in-part of U.S. patent application Ser. No. 18/755,599, filed Jun. 26, 2024, which claims the benefit of U.S. Provisional Application 63/524,272 filed on Jun. 30, 2023, the entire contents of which are each incorporated herein by reference.

### FIELD OF THE DISCLOSURE

The present disclosure relates generally to substrate processing systems having expanded substrate processing capabilities. Some more particular aspects of this technology relate to substrate processing systems including a front end, an inboard substrate handling chamber, a load-lock module between the front end and the inboard substrate handling chamber, and an outboard substrate handling chamber interconnected with the inboard substrate handling chamber by an additional outboard load-lock module.

### BACKGROUND OF THE DISCLOSURE

Material layers are commonly deposited onto substrates during fabrication of semiconductor devices, such as during fabrication of integrated circuits and electronic devices. Material layer deposition generally is accomplished by supporting a substrate within a substrate processing chamber arrangement, heating the substrate to a desired deposition temperature, and flowing one or more material layer precursors through the chamber arrangement and across the substrate. As the precursor flows across the substrate, the material layer progressively develops onto the surface of the substrate, typically according to the temperature of the substrate and environmental conditions within the chamber arrangement.

Existing substrate processing systems 100 include “cluster type” systems of the type generally shown in FIG. 1. Such substrate processing systems 100 include a substrate handling chamber 102 that operatively connects with two to four substrate processing chambers 104 via gate valves 106. Each substrate processing chamber 104 is equipped to receive a substrate on a substrate support 108 that holds the substrate during processing (e.g., during material layer deposition as described above).

The substrate handling chamber 102 includes robotic arm 110 used to move substrates into and out of the various substrate processing chambers 104 through the gate valves 106. In use, a gate valve 106 is opened, an end effector 110A of the robotic arm 110 extends through the open gate valve 106 to insert a substrate into or remove a substrate from an interior chamber of the substrate processing chamber 104 (e.g., placing a substrate on or taking a substrate off the substrate support 108). Once the robotic arm 110 is retracted from the substrate processing chamber 104, the gate valve 106 is closed, thereby sealing the substrate processing chamber 104 from the substrate handling chamber 102. Then, other desired actions can take place in the substrate processing chamber 104 and/or the substrate handling chamber 102.

FIG. 1 further shows that this substrate processing system 100 includes a load-lock module 112. The load-lock module 112 is connected with the substrate handling chamber 102 by gate valve 116. The load-lock module 112 includes substrate holding components 114 for holding substrates on the way into the substrate handling chamber 102 for further processing and on the way out of the substrate handling chamber 102 (after processing is complete). The end effector 110A of robotic arm 110 moves through the gate valve 116 (when opened) to move substrates from the load-lock module 112 into the substrate handling chamber 102 (for layer deposition and other processing) and from the substrate handling chamber 102 into the load-lock module 112 (after processing is completed). The load-lock module 112 and gate valve 116 keep the substrates isolated from the environment of the substrate handling chamber 102 until the conditions (e.g., temperature, pressure, content of atmosphere, etc.) within the substrate handling chamber 102 are ready for the substrate(s) to be inserted.

The load-lock module 112 further is coupled with an equipment front end module 120 via another gate valve 118. The equipment front end module 120 includes a robotic arm 122. The end effector 122A of that robotic arm 122 moves through the gate valve 118 (when opened) to move substrates from the equipment front end module 120 into the load-lock module 112 (for layer deposition and other processing) and from the load-lock module 112 into the equipment front end module 120 (after processing is completed). The robotic arm 122 of the equipment front end module 120 also picks up new substrates for processing from one of the load ports 124A-124C and returns processed substrates to one of the load ports 124A-1240C, e.g., to be transported to another location for further processing.

Conventional semiconductor production systems and methods of this type generally have been acceptable for their intended purpose, but there is room for improvement. Improvements that reduce manufacturing costs, reduce processing time, and/or improve manufacturing efficiency would be welcome advances in the art.

### SUMMARY OF THE DISCLOSURE

Aspects of this technology relate to substrate processing systems and methods having expanded substrate processing capabilities. As noted above, some more particular aspects of this technology relate to substrate processing systems and methods including and using an inboard substrate handling chamber and an outboard substrate handling chamber interconnected by an additional outboard load-lock module. This arrangement and these additional components increase the number of substrate processing chambers and substrate processing capabilities in an overall substrate processing system.

Semiconductor or other substrate processing systems in accordance with at least some examples of this technology may include a first substrate handling chamber having: (a) a first facet, (b) a second facet extending at an oblique angle with respect to the first facet, (c) a third facet extending at an oblique angle with respect to the first facet, (d) a fourth facet extending at an oblique angle with respect to the second facet, (e) a fifth facet extending at an oblique angle with respect to the third facet, and (f) a sixth facet connected between the fourth facet and the fifth facet. A first load-lock module is connected with the first facet, and this first load-lock module includes one or more first substrate supports for holding substrates moving into and out of the first substrate handling chamber through the first facet. A second load-lock module is connected with the sixth facet. The systems further include a second substrate handling chamber having: (a) a seventh facet connected with the second load-lock module, (b) an eighth facet extending at an oblique angle with respect to the seventh facet, (c) a ninth facet extending at an oblique angle with respect to the seventh facet, (d) a tenth facet extending at an oblique angle with respect to the eighth facet, and (e) an eleventh facet extending at an oblique angle with respect to the ninth facet. The second load-lock module includes one or more second substrate supports for holding substrates transferring between the first substrate handling chamber and the second substrate handling chamber through the sixth facet and the seventh facet.

In addition to one or more of the features described above, or as an alternative, the eleventh facet may extend at an oblique angle with respect to the tenth facet.

In addition to one or more of the features described above, or as an alternative, each of the second facet, the third facet, the eighth facet, the ninth facet, the tenth facet, and the eleventh facet may be connected with a gate valve that is configured to connect with a respective substrate processing module.

In addition to one or more of the features described above, or as an alternative, examples of substrate processing systems in accordance with this technology may include: (i) a first substrate processing chamber releasably coupled with the second facet; (ii) a second substrate processing chamber releasably coupled with the third facet; (iii) a third substrate processing chamber releasably coupled with the eighth facet; (iv) a fourth substrate processing chamber releasably coupled with the ninth facet; (v) a fifth substrate processing chamber releasably coupled with the tenth facet; and/or (vi) a sixth substrate processing chamber releasably coupled with the eleventh facet.

In addition to one or more of the features described above, or as an alternative, one or more (and optionally each) of the first substrate processing chamber, the second substrate processing chamber, the third substrate processing chamber, the fourth substrate processing chamber, the fifth substrate processing chamber, and/or the sixth substrate processing chamber may include at least four substrate supports.

In addition to one or more of the features described above, or as an alternative, one or more (and optionally each) of the first substrate processing chamber, the second substrate processing chamber, the third substrate processing chamber, the fourth substrate processing chamber, the fifth substrate processing chamber, and/or the sixth substrate processing chamber may include at least two substrate supports.

In addition to one or more of the features described above, or as an alternative: (a) the fourth facet may have an edge-to-edge dimension that is shorter than edge-to-edge dimensions of each of the first facet, the second facet, the third facet, and the sixth facet, and/or (b) the fifth facet may have an edge-to-edge dimension that is shorter than the edge-to-edge dimensions of each of the first facet, the second facet, the third facet, and the sixth facet.

In addition to one or more of the features described above, or as an alternative, the edge-to-edge dimension of the fourth facet and the edge-to-edge dimension of the fifth facet may be substantially equal, and/or the edge-to-edge dimensions of the first facet, the second facet, the third facet, and the sixth facet may be substantially equal.

In addition to one or more of the features described above, or as an alternative, the sixth facet may have an edge-to-edge dimension that is substantially equal to an edge-to-edge dimension of the seventh facet.

In addition to one or more of the features described above, or as an alternative, edge-to-edge dimensions of each of the eighth facet, the ninth facet, the tenth facet, and the eleventh facet may be substantially equal to the edge-to-edge dimension of the seventh facet.

In addition to one or more of the features described above, or as an alternative, the oblique angle defined between the first facet and the second facet may be substantially equal to the oblique angle defined between the first facet and the third facet; and/or the oblique angle defined between the seventh facet and the eighth facet may be substantially equal to the oblique angle defined between the seventh facet and the ninth facet.

In addition to one or more of the features described above, or as an alternative, the oblique angle defined between the first facet and the second facet may be substantially equal to the oblique angle defined between the seventh facet and the eighth facet.

In addition to one or more of the features described above, or as an alternative, an outer perimeter of the second substrate handling chamber extending around the seventh facet, the eighth facet, the ninth facet, the tenth facet, and the eleventh facet forms a regular pentagon.

In addition to one or more of the features described above, or as an alternative, an outer perimeter of the first substrate handling chamber extending around the first facet, the second facet, the third facet, the fourth facet, the fifth facet, and the sixth facet forms a hexagon having four sides of a first length and two sides of a second length that is shorter than the first length.

In addition to one or more of the features described above, or as an alternative, the first load-lock module and the second load-lock module may be interchangeable with one another. In addition to one or more of the features described above, or as an alternative, each of the first load-lock module and the second load-lock module may include substrate transfer ports arranged in a 2×2 matrix.

In addition to one or more of the features described above, or as an alternative, the fourth facet and/or the fifth facet may constitute completely closed and sealed walls.

In addition to one or more of the features described above, or as an alternative, the fourth facet may include at least one substrate transfer slot, and/or the fifth facet may include at least one substrate transfer slot.

Semiconductor or other substrate processing methods may use substrate processing systems having any of the features and/or combinations of features described above.

Semiconductor or other substrate processing methods in accordance with at least some examples of this technology may include moving a first substrate from a first load-lock module into a first substrate handling chamber, wherein the first substrate handling chamber includes: (a) a first facet, (b) a second facet extending at an oblique angle with respect to the first facet, (c) a third facet extending at an oblique angle with respect to the first facet, (d) a fourth facet extending at an oblique angle with respect to the second facet, (e) a fifth facet extending at an oblique angle with respect to the third facet, and (f) a sixth facet connected between the fourth facet and the fifth facet, and wherein the first substrate is moved from the first load-lock module into the first substrate handling chamber through the first facet. The method further may include: (i) moving the first substrate from the first substrate handling chamber into a first substrate processing module, wherein the first substrate processing module is connected with one of the second facet or the third facet; (ii) performing a first treatment process on the first substrate in the first substrate processing module; (iii) moving the first substrate from the first substrate processing module into the first substrate handling chamber; (iv) moving the first substrate from the first substrate handling chamber through the sixth facet into a second load-lock module connected with the sixth facet; and (v) moving the first substrate from the second load-lock module into a second substrate handling chamber. The second substrate handling chamber may include: (a) a seventh facet connected with the second load-lock module, (b) an eighth facet extending at an oblique angle with respect to the seventh facet, (c) a ninth facet extending at an oblique angle with respect to the seventh facet, (d) a tenth facet extending at an oblique angle with respect to the eighth facet, and (e) an eleventh facet extending at an oblique angle with respect to the ninth facet. In this method, the first substrate is moved from the second load-lock module into the second substrate handling chamber through the seventh facet. The method further may include: (i) moving the first substrate from the second substrate handling chamber into a second substrate processing module, wherein the second substrate processing module is connected with one of the eighth facet, the ninth facet, the tenth facet, or the eleventh facet; and (ii) performing a second treatment process on the first substrate in the second substrate processing module.

In addition to one or more of the features described above, or as an alternative, methods in accordance with at least some examples of this technology may include: (a) moving the first substrate from the second substrate processing module into the second substrate handling chamber; (b) moving the first substrate from the second substrate handling chamber through the seventh facet and into the second load-lock module; (c) moving the first substrate from the second load-lock module through the sixth facet and into the first substrate handling chamber; and (d) moving the first substrate from the first substrate handling chamber through the first facet and into the first load-lock module.

In addition to one or more of the features described above, or as an alternative, methods in accordance with at least some examples of this technology may use semiconductor or other substrate processing systems having any of the features and/or combinations of features described above.

In accordance with further aspects as described herein, a semiconductor processing system may comprise a front end configured to receive a substrate, a first substrate handling chamber, a first load-lock module configured to pass the substrate between the front end and the first substrate handling chamber, a second substrate handling chamber, and a second load-lock module configured to pass the substrate between the first substrate handling chamber and the second substrate handling chamber. The first load-lock module may comprise a first connection structure configured to connect with the front end, and a second connection structure configured to connect with the first substrate handling chamber. The second load-lock module may comprise a third connection structure, substantially the same as the first connection structure, configured to connect with the first substrate handling chamber, and a fourth connection structure, substantially the same as the second connection structure, configured to connect with the second substrate handling chamber. The first connection structure may comprise a first configuration of connectors and the second connection structure comprises a second configuration of connectors. The first load-lock module and the second load-lock module may comprise one or both of the same components or the same structures. The first load-lock module and the second load-lock module may be interchangeable in the semiconductor processing system. The first load-lock module and the second load-lock module may have the same transfer port configuration. The first load-lock module may be configured to perform at least one of actively heating the substrate or actively cooling the substrate, and the second load-lock module may be configured to pass the substrate between the first substrate handling chamber and the second substrate handling chamber without actively heating the substrate and without actively cooling the substrate, or vice-versa. A facet of the first load-lock module facing the front end, and a facet of the second load-lock module facing the first substrate handling chamber, may have edge-to-edge dimensions that are substantially equal to each other. A facet of the first load-lock module facing the first substrate handling chamber, and a facet of the second load-lock module facing the second substrate handling chamber, may have edge-to-edge dimensions that are substantially equal to each other. The semiconductor processing system may further comprise a first semiconductor processing chamber connected to the first substrate handling chamber and configured to perform a first treatment process on the substrate, and a second semiconductor processing chamber connected to the second substrate handling chamber and configured to perform a second treatment process on the substrate.

In accordance with further aspects as described herein, a semiconductor processing system may comprise a first substrate handling chamber, a first load-lock module configured to pass the substrate between a front end and the first substrate handling chamber, a second substrate handling chamber, and a second load-lock module configured to pass the substrate between the first substrate handling chamber and the second substrate handling chamber. The first load-lock module and the second load-lock module may be interchangeable in the semiconductor processing system. The first load-lock module and the second load-lock module may share substantially identical connection structures. The first load-lock module and the second load-lock module may comprise one or both of the same components or the same structures. The first load-lock module and the second load-lock module may have the same transfer port configuration. The first load-lock module may be configured to perform at least one of actively heating the substrate or actively cooling the substrate, and the second load-lock module is configured to pass the substrate between the first substrate handling chamber and the second substrate handling chamber without actively heating the substrate and without actively cooling the substrate, or vice-versa. A facet of the first load-lock module facing the front end, and a facet of the second load-lock module facing the first substrate handling chamber, may have edge-to-edge dimensions that are substantially equal to each other. A facet of the first load-lock module facing the first substrate handling chamber, and a facet of the second load-lock module facing the second substrate handling chamber, may have edge-to-edge dimensions that are substantially equal to each other. The semiconductor processing system may further comprise a first semiconductor processing chamber connected to the first substrate handling chamber and configured to perform a first treatment process on the substrate, and a second semiconductor processing chamber connected to the second substrate handling chamber and configured to perform a second treatment process on the substrate.

In accordance with further aspects as described herein, a method may be performed using a semiconductor processing system. The method may comprise moving a substrate from a first load-lock module into a first substrate handling chamber, and moving the substrate from the first substrate handling chamber into a first substrate processing module. The method may further comprise performing a first treatment process on the substrate in the first substrate processing module. The method may further comprise moving the substrate from the first substrate processing module into the first substrate handling chamber, and moving the substrate from the first substrate handling chamber into a second load-lock module. The method may further comprise moving the substrate from the second load-lock module into a second substrate handling chamber, and moving the substrate from the second substrate handling chamber into a second substrate processing module. The method may further comprise performing a second treatment process on the substrate in the second substrate processing module. The first load-lock module and the second load-lock module may be interchangeable in the semiconductor processing system. The first load-lock module and the second load-lock module may share substantially identical connection structures. A facet of the first load-lock module facing a front end of the semiconductor processing system, and a facet of the second load-lock module facing the first substrate handling chamber, may have edge-to-edge dimensions that are substantially equal to each other. A facet of the first load-lock module facing the first substrate handling chamber, and a facet of the second load-lock module facing the second substrate handling chamber, may have edge-to-edge dimensions that are substantially equal to each other.

This summary is provided to introduce a selection of concepts relating to this technology in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a basic, prior art cluster type substrate processing system;

FIG. 2 is a schematic view of a substrate processing system in accordance with some examples and aspects of this technology;

FIG. 3A is a larger view showing the first substrate handling chamber in accordance with some examples and aspects of this technology;

FIG. 3B is a larger view showing the second substrate handling chamber in accordance with some examples and aspects of this technology;

FIG. 3C provides a view comparing a first substrate handling chamber and a second substrate handling chamber in accordance with some examples and aspects of this technology;

FIG. 4 is a schematic view of another substrate processing system in accordance with some examples and aspects of this technology;

FIG. 5 provides a schematic view of substrate transfer slots in load-lock modules in accordance with some examples and aspects of this technology; and

FIG. 6 provides a view of another example first substrate handling chamber in accordance with some examples and aspects of this technology.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION

Reference now will be made to the drawings wherein like reference numerals identify similar structural features or aspects of the subject disclosure.

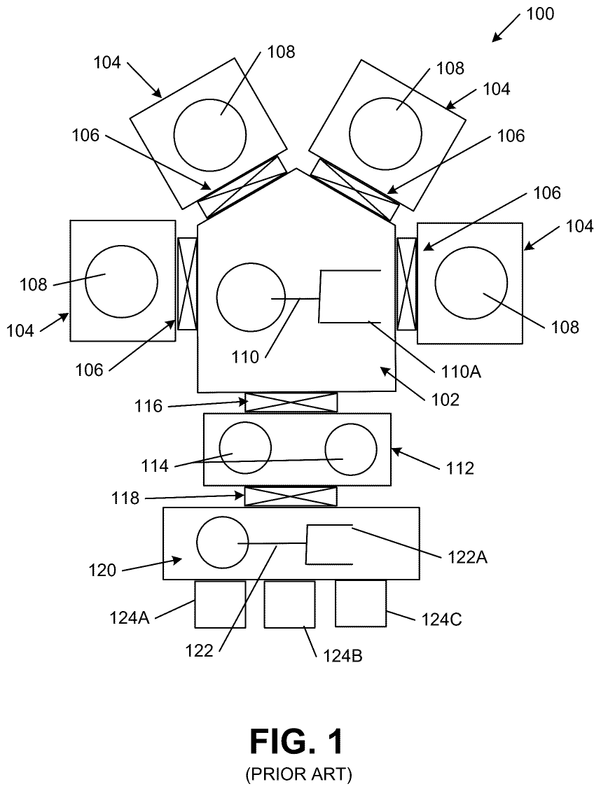

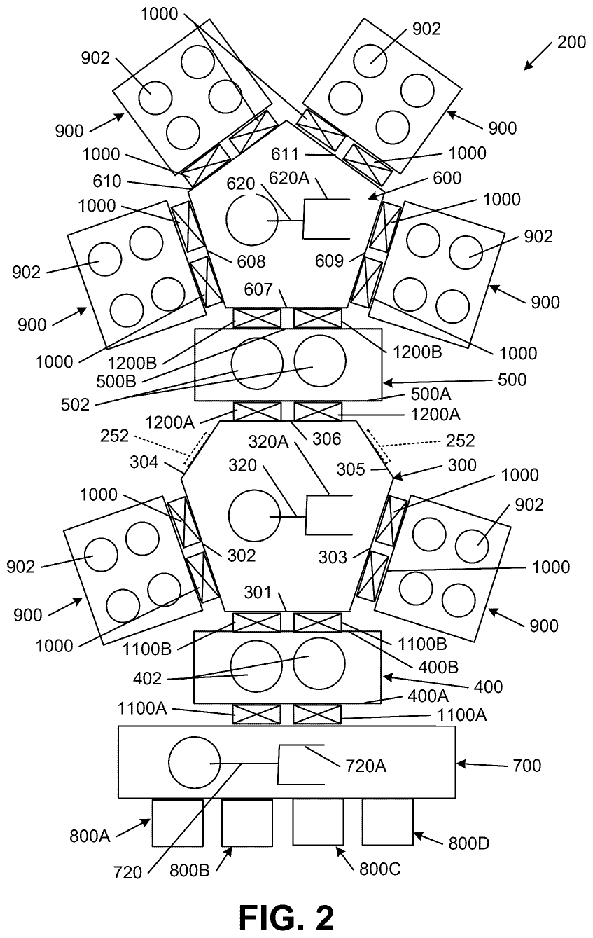

FIG. 2 schematically illustrates an overhead view of a substrate processing system 200 (e.g., a cluster type semiconductor processing system) having expanded substrate processing capabilities in accordance with some examples of this technology. This substrate processing system 200 expands substrate processing capabilities at least by adding an additional substrate handling chamber and one or more additional substrate processing chambers as compared to the basic substrate processing system 100 shown in FIG. 1.

More particularly, the substrate processing system 200 shown in FIG. 2 includes:

(a) a first substrate handling chamber 300 (an “inboard” substrate handling chamber) including a first robotic arm 320 having an end effector 320A; (b) a first load-lock module 400 (an “inboard” load-lock module) connected at one edge or facet of the first substrate handling chamber 300; (c) a second load-lock module 500 (an “outboard” load-lock module) connected at the opposite edge or facet of the first substrate handling chamber 300; and (d) a second substrate handling chamber 600 (an “outboard” substrate handling chamber) including a second robotic arm 620 having an end effector 620A. The second load-lock module 500 extends between and connects the first substrate handling chamber 300 and the second substrate handling chamber 600. The first robotic arm 320 may be identical to, or otherwise interchangeable with, the second robotic arm 620. The end effector 320A may be identical to, or otherwise interchangeable with, the end effector 620A. The first load-lock module 400 of this example also is connected with an equipment front end module 700 that includes a third robotic arm 720 having an end effector 720A. The equipment front end module 700 may include or connect with a nitrogen gas source for providing a nitrogen gas atmosphere within the equipment front end module 700. The equipment front end module 700 receives new substrates for processing into the substrate processing system 200 and discharges processed substrates from the substrate processing system 200 via one or more loading ports 800A-800D (moving the substrates between the loading port(s) 800A-800D and the first load-lock module 400 using the robotic arm 720). While four loading ports 800A-800D are shown in the example of FIG. 2, more or fewer loading ports may be provided in other examples of this technology.

Each of the first substrate handling chamber 300 and the second substrate handling chamber 600 is connected with multiple substrate processing chambers 900. Substrates are transferred into the substrate processing chambers 900 where one or more layers of material are deposited onto a surface of the substrate and/or other desired substrate processing takes place. FIG. 2 shows each substrate processing chamber 900 including four substrate supports 902 onto which substrates can be placed during processing. More or fewer substrates supports 902 may be provided in each substrate processing chamber 900 (e.g., the substrate processing chambers 900 may be dual chamber modules (DCM) or quad chamber modules (QCM)). Substrate processing chambers 900 in accordance with some examples of this technology may include another four substrate supports 902 located vertically beneath the four substrate supports 902 shown in the top view of FIG. 2. Each of the substrate processing chambers 900 may have the same structures or one or more of the substrate processing chambers 900 may have a different structure from other substrate processing chambers 900 present.

Each of the first substrate handling chamber 300 and the second substrate handling chamber 600 is connected with its respective substrate processing chambers 900 via one or more gate valves 1000. While two gate valves 1000 are shown connecting substrate handling chambers 300, 600 with each of their respective substrate processing chambers 900, more or fewer gate valves 1000 may be provided with each substrate processing chamber 900, in other examples of this technology. Substrate processing chambers 900 in accordance with some examples of this technology may be connected with their respective substrate handling chamber 300, 600 by another two gate valves 1000, e.g., located vertically beneath the two gate valves 1000 shown in the top view of FIG. 2. When closed, the gate valves 1000 sealingly separate the substrate handling chambers 300, 600 from their respective substrate processing chambers 900 (so that independent atmospheric conditions may be maintained in each chamber). When open, the gate valves 1000 provide an opening (e.g., a substrate transfer slot) through which the end effector 320A, 620A of a robotic arm 320, 620 can extend to move substrates into and out of the substrate processing chamber 900. The openings through the gate valves 1000 align with substrate transfer slots provided in the substrate processing chambers 900 and the substrate handling chambers 300, 600, to enable substrates to be moved between the substrate processing chambers 900 and the substrate handling chambers 300, 600 through the gate valves 1000. Each of gate valves 1000 may have the same structures or one or more of the gate valves 1000 may have a different structure from other gate valves 1000 present.

One face of the first load-lock module 400 connects with the equipment front end module 700 by one or more gate valves 1100A (two shown in FIG. 2), and the opposite face of the first load-lock module 400 connects with the first substrate handling chamber 300 by one or more gate valves 1100B. The first load-lock module 400 further includes one or more substrate supports 402 (two shown in FIG. 2) for holding substrates while they wait to be moved into the equipment front end module 700 or the first substrate handling chamber 300. When closed, the gate valves 1100A, 1100B sealingly separate the load-lock module 400 from the equipment front end module 700 and the substrate handling chamber 300 (so that independent atmospheric conditions may be maintained in each chamber). When open, the gate valves 1100A provide an opening (e.g., a substrate transfer slot) through which the end effector 720A of robotic arm 720 can extend to move substrates into and out of the equipment front end module 700. The openings through the gate valves 1100A align with substrate transfer slots provided in the equipment front end module 700 and the first load-lock module 400 to enable substrates to be moved between the equipment front end module 700 and the first load-lock module 400 through gate valves 1100A. When open, the gate valves 1100B provide an opening (e.g., a substrate transfer slot) through which the end effector 320A of robotic arm 320 can extend to move substrates into and out of the substrate handling chamber 300. The openings through the gate valves 1100B align with substrate transfer slots provided in the substrate handling chamber 300 and the first load-lock module 400 to enable substrates to be moved between the substrate handling chamber 300 and the first load-lock module 400 through gate valves 1100B. Each of gate valves 1100A, 1100B may have the same structure or one or more of the gate valves 1100A, 1100B may have a different structure from other gate valves 1100A, 1100B present.

In the substrate processing system 200 of FIG. 2, one face of the second load-lock module 500 connects with the first substrate handling chamber 300 by one or more gate valves 1200A (two shown in FIG. 2), and the opposite face of the second load-lock module 500 connects with the second substrate handling chamber 600 by one or more gate valves 1200B. The second load-lock module 500 further includes one or more substrate supports 502 (two shown in FIG. 2) for holding substrates while they wait to be moved between the two substrate handling chambers 300, 600. When closed, the gate valves 1200A, 1200B sealingly separate the second load-lock module 500 from the two substrate handling chambers 300, 600 (so that independent atmospheric conditions may be maintained in each chamber). When open, the gate valves 1200A provide an opening (e.g., a substrate transfer slot) through which the end effector 320A of robotic arm 320 can extend to move substrates into and out of the first substrate handling chamber 300. The openings through the gate valves 1200A align with substrate transfer slots provided in the first substrate handling chamber 300 and the second load-lock module 500 to enable substrates to be moved between the substrate handling chamber 300 and the second load-lock module 500 through gate valves 1200A. When open, the gate valves 1200B provide an opening (e.g., a substrate transfer slot) through which the end effector 620A of robotic arm 620 can extend to move substrates into and out of the second substrate handling chamber 600. The openings through the gate valves 1200B align with substrate transfer slots provided in the second substrate handling chamber 600 and the second load-lock module 500 to enable substrates to be moved between the second substrate handling chamber 600 and the second load-lock module 500 through gate valves 1200B. Each of gate valves 1200A, 1200B may have the same structure or one or more of the gate valves 1200A, 1200B may have a different structure from other gate valves 1200A, 1200B present. Gate valves 1200A and/or 1200B also may have the same or different structures from gate valves 1100A and/or 1100B.

The first lock-load module 400 may have the same structure as the second load-lock module 500 and/or the first and second load-lock modules 400, 500 may be interchangeable (e.g., so that load-lock modules 400, 500 can switch positions and/or have a modular structure). In other examples, the first lock-load module 400 and the second load-lock module 500 may have different structures and/or may not be interchangeable (e.g., so that load-lock modules 400, 500 cannot switch positions in the substrate processing system 200). Either or both load-lock modules 400, 500 may be multi-station cooling and/or heating capable and/or pass-through types. For example, either or both load-lock modules 400, 500 may or may not have heaters and/or chill plates, and either or both load-lock modules 400, 500 may or may not utilize gate valves for pressurization and/or depressurization as part of transferring a substrate. For example, while gate valves 1100A, 1100B, 1200A, and 1200B are shown in FIG. 2, any of these gate valves may be included or not included as desired.

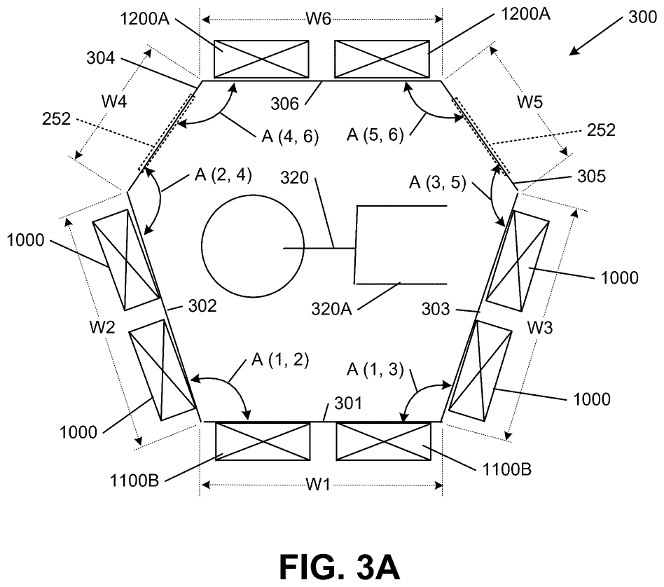

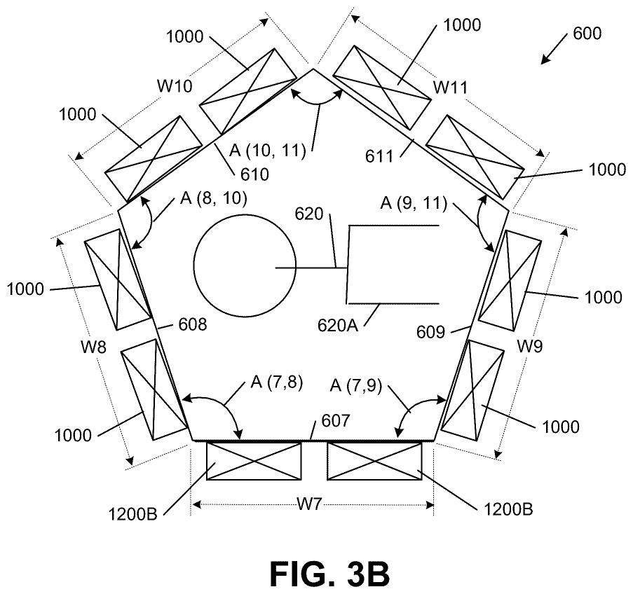

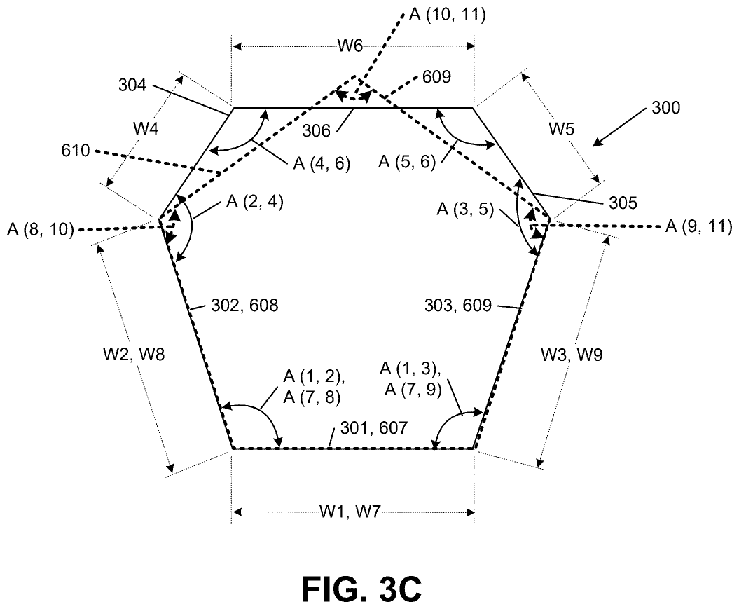

Additional aspects of this substrate processing system 200 will be discussed in more detail below in conjunction with FIGS. 3A-3C. FIG. 3A provides an enlarged view of the first substrate handling chamber 300 from FIG. 2, and FIG. 3B provides an enlarged view of the second substrate handling chamber 600 from FIG. 2 (“enlarged” as compared to the appearance of these components in FIG. 2). FIG. 3C provides a view comparing features of the first substrate handling chamber 300 and the second substrate handling chamber 600 in this example substrate processing system 200. Where the same reference numbers are used in FIGS. 3A-C as used in FIG. 2, the same or similar parts are being referenced, and much of the repetitive description may be omitted.

FIG. 3A shows the first substrate handling chamber 300 having multiple “facets” (i.e., exposed outer surfaces, e.g., to which other substrate processing system 200 components may connect, such as gate valves 1000, 1100B, 1200A). While it can be an entire side or face of the first substrate handling chamber 300, a “facet” need not extend an entire vertical height and/or an entire horizontal width of a side face of the first substrate handling chamber 300. Rather, a “facet” may provide only the mounting surface for connecting that side or face of the first substrate handling chamber 300 with another component. This example first substrate handling chamber 300 includes: (a) a first facet 301, (b) a second facet 302 extending at an oblique angle A (1, 2) with respect to the first facet 301, (c) a third facet 303 extending at an oblique angle A (1, 3) with respect to the first facet 301, (d) a fourth facet 304 extending at an oblique angle A (2, 4) with respect to the second facet 302, (e) a fifth facet 305 extending at an oblique angle A (3, 5) with respect to the third facet 303, and (f) a sixth facet 306 connected between the fourth facet 304 and the fifth facet 305. Each of the angles A (4, 6) and A (5, 6) (the angle of the sixth facet 306 with respect to the fourth facet 304 and the angle of the sixth facet 306 with respect to the fifth face 305) also is an oblique angle. As shown in FIG. 3A, an outer perimeter of the first substrate handling chamber 300 may have a generally hexagonal shape (and/or at least its facets 301-306 may be arranged in a generally hexagonal shape). In this specifically illustrated example, however, the first facet 301, the second facet 302, the third facet 303, and the sixth facet 306 are the same size and are larger than the fourth facet 304 and the fifth facet 305. The fourth facet 304 and fifth facet 305 also may be the same size.

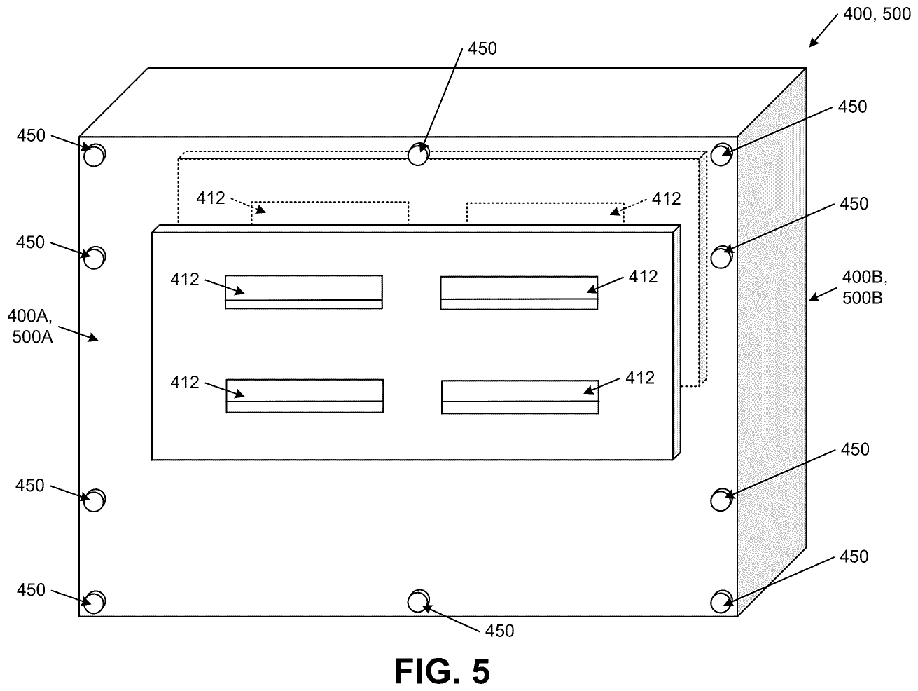

As discussed above, the first load-lock module 400 connects with the first substrate handling chamber 300, and this connection is made at the first facet 301 (through gate valves 1100B). Thus, the first facet 301 may have substrate transfer slots that correspond to locations of substrate transfer slots provided in the gate valves 1100B and in the load-lock module 400. In some examples, the first facet 301 may have substrate transfer slots arranged in a 2×2 matrix, e.g., akin to the substrate transfer port 412 positions in the load-lock modules 400, 500 shown in FIG. 5 (and discussed in more detail below). Substrates move into and out of the first substrate handling chamber 300 through the first facet 301 and through gate valves 1100B.

As also discussed above, the first substrate handling chamber 300 connects with the second load-lock module 500, and this connection is made at the sixth facet 306 (through gate valves 1200A). Sixth facet 306 may extend parallel with the first facet 301 and may be located on the opposite side of the first substrate handling chamber 300 from the first facet 301. The sixth facet 306 may have substrate transfer slots that correspond to locations of substrate transfer slots provided in the gate valves 1200A and in the load-lock module 500. In some examples, the sixth facet 306 may have substrate transfer slots arranged in a 2×2 matrix, e.g., akin to the substrate transfer port 412 positions in the load-lock modules 400, 500 shown in FIG. 5 (and discussed in more detail below). Substrates move into and out of the first substrate handling chamber 300 and into and out of the second load-lock module 500 through the sixth facet 306 and through gate valves 1200A.

FIG. 3B shows the second substrate handling chamber 600 also having multiple “facets” (i.e., exposed outer surfaces, e.g., to which other substrate processing system 200 components may connect, such as gate valves 1000, 1200B). While it can be an entire side or face of the second substrate handling chamber 600, a “facet” need not extend an entire vertical height and/or an entire horizontal width of a side face of the second substrate handling chamber 600. Rather, a “facet” may provide only the mounting surface for connecting that side or face of the second substrate handling chamber 600 with another component. This example second substrate handling chamber 600 includes: (a) a seventh facet 607 (which connects with the second load-lock module 500 through gate valves 1200B); (b) an eighth facet 608 extending at an oblique angle A (7, 8) with respect to the seventh facet 607; (c) a ninth facet 609 extending at an oblique angle A (7, 9) with respect to the seventh facet 607; (d) a tenth facet 610 extending at an oblique angle A (8, 10) with respect to the eighth facet 608; and (e) an eleventh facet 611 extending at an oblique angle A (9, 11) with respect to the ninth facet 609. The tenth facet 610 also may extend at an oblique angle A (10, 11) with respect to the eleventh facet 611. As shown in FIG. 3B, an outer perimeter of the second substrate handling chamber 600 may have a generally pentagonal shape (and/or at least its facets 607-611 may be arranged in a generally pentagonal shape). In this specifically illustrated example, the seventh facet 607, the eighth facet 608, the ninth facet 609, the tenth facet 610, and the eleventh facet 611 are the same size. Thus, the pentagonal shape for second substrate handling chamber 600 shown in FIG. 3B is a regular pentagonal shape, and all angles A (7, 8), A (7, 9), A (8, 10), A (9, 11), and A (10, 11) are the same size (e.g., about 108 degrees).

As discussed above, the second load-lock module 500 connects with the second substrate handling chamber 600, and this connection is made at the seventh facet 607 (through gate valves 1200B). Substrates move between the second substrate handling chamber 600 and the first substrate handling chamber 300 through the second load-lock module 500, through gate valves 1200A and 1200B, and through the sixth facet 306 and the seventh facet 607. The sixth facet 306 and the seventh facet 607 may extend parallel to one another (and parallel with the first facet 301) and connect with opposite sides of the second load-lock module 500. The seventh facet 607 may have substrate transfer slots that correspond to locations of substrate transfer slots provided in the gate valves 1200B and in the load-lock module 500. In some examples, the seventh facet 607 may have substrate transfer slots arranged in a 2×2 matrix, e.g., akin to the substrate transfer port 412 positions in the load-lock modules 400, 500 shown in FIG. 5 (and discussed in more detail below).

FIGS. 2-3B further show that each of the second facet 302, the third facet 303, the eighth facet 608, the ninth facet 609, the tenth facet 610, and the eleventh facet 611 is connected with one or more gate valves 1000. The gate valves 1000 are further configured to connect with a respective substrate processing chamber 900. More specifically, as shown in FIG. 2: (a) a first substrate processing chamber 900 may be releasably coupled with the second facet 302 via gate valve(s) 1000; (b) a second substrate processing chamber 900 may be releasably coupled with the third facet 303 via gate valve(s) 1000; (c) a third substrate processing chamber 900 may be releasably coupled with the eighth facet 608 via gate valve(s) 1000; (d) a fourth substrate processing chamber 900 may be releasably coupled with the ninth facet 609 via gate valve(s) 1000; (e) a fifth substrate processing chamber 900 may be releasably coupled with the tenth facet 610 via gate valve(s) 1000; and (f) a sixth substrate processing chamber 900 may be releasably coupled with the eleventh facet 611 via gate valve(s) 1000. Each of the substrate processing chambers 900 may include at least one substrate support 902 (and in some examples, at least two substrate supports 902, at least four substrate supports 902, or even up to 8 (or more) substrate supports 902).

Returning to FIG. 3A, at least some portions of the sides or faces of the first substrate handling chamber 300 may have a generally hexagonal shape (or at least the facets 301-306 thereof may be arranged along sides of a generally hexagonal shape), but it need not be a regular hexagonal shape. For example, as shown in FIG. 3A, the first facet 301 may have a width W1, the second facet 302 may have a width W2, the third facet 303 may have a width W3, and the sixth facet 306 may have a width W6, and these widths (W1, W2, W3, W6) may be substantially equal. The term “substantially equal” as used herein in this context, means that the two widths being compared are equal or within 5% of each other (e.g., W1=W2±(W2×0.05)). Additionally, the fourth facet 304 may have a width W4 and the fifth facet 305 may have a width W5, and these widths W4 and W5 may be substantially equal. In this example, however, the widths W4 and W5 are smaller (shorter) than the widths W1, W2, W3, and W6 and are not substantially equal to those widths. These “widths” constitute an edge-to-edge dimension of the facets 301-306 (which may correspond to the edge-to-edge dimension of an entire side or face of the substrate handling chamber 300 or an edge-to-edge dimension of the portion of the side or face that connects with another component).

Similarly, as shown in FIG. 3B, the seventh facet 607 may have a width W7, the eighth facet 608 may have a width W8, the ninth facet 609 may have a width W9, the tenth facet 610 may have a width W10, and the eleventh facet 611 may have a width W11, and these widths (W7, W8, W9, W10, and W11) may be substantially equal (as defined above). These “widths” constitute an edge-to-edge dimension of the facets 607-611 (which may correspond to the edge-to-edge dimension of an entire side or face of the substrate handling chamber 600 or an edge-to-edge dimension of the portion of the side or face that connects with another component). Additionally, in at least some examples of this technology, the sixth facet 306 may have a width W6 (an edge-to-edge dimension) that is substantially equal to the width W7 (edge-to-edge dimension) of the seventh facet 607. Thus, in at least some examples of this technology, the first facet 301, second facet 302, third facet 303, sixth facet 306, seventh facet 607, eighth facet 608, ninth facet 609, tenth facet 610, and eleventh facet 611 may be substantially equal (e.g., have substantially equal edge-to-edge dimensions).

The angles defined by the facets of the first substrate handling chamber 300 are not all substantially equal in the example structure shown in FIGS. 2 and 3A (the term “substantially equal” as used herein in this context, means that the two angles being compared are equal or within 5 degrees of each other (e.g., Angle 1=Angle 2±5 degrees)). In at least some examples of this technology (and in the structure shown in FIGS. 2 and 3A): (i) angle A (1, 2) may be substantially equal to angle A (1, 3); (ii) angle A (2, 4) may be substantially equal to angle A (3, 5); and (iii) angle A (4, 6) may be substantially equal to angle A (5, 6). Additionally, if desired, angles A (2, 4), A (3, 5), A (4, 6), and A (5, 6) may be substantially equal to one another. In this illustrated example, angles A (1, 2) and A (1, 3) may be smaller than (and optionally not substantially equal to) angles A (2, 4), A (3, 5), A (4, 6), and A (5, 6).

FIG. 3C shows the size and shape of the pentagon structure of the second substrate handling chamber 600 as broken lines overlaid on the hexagonal size and shape of the first substrate handling chamber 300 to compare sizes and shapes in this example. As shown in this figure: (i) widths W1, W2, and W3 are substantially equal to widths W7, W8, and W9, respectively, and (ii) angles A (1, 2) and A (1, 3) are substantially equal to angles A (7, 8) and A (7, 9), respectively. In one more specific example, these angles A (1, 2), A (1, 3), A (7, 8), and A (7, 9) may be about 108 degrees. Angles A (2, 4), A (3, 5), A (4, 6), and A (5, 6) are somewhat larger and may be substantially equal, e.g., about 126 degrees.

As evident from the discussion above, the substrate processing system 200 described in conjunction with FIGS. 2-3C has increased substrate processing capabilities at least based on the one or more additional substrate processing chambers 900 connected with the second facet 302 and/or third facet 303 of the first (inboard) substrate handling chamber 300. In some examples of this technology, the fourth facet 304 and the fifth facet 305 of the substrate handling chamber 300 may constitute completely closed and sealed walls. In such structures, the fourth facet 304 and/or the fifth facet 305 may be left empty to provide room, e.g., for access to the first substrate handling chamber 300, the second load-lock module 500, and/or some of the substrate processing chambers 900 for maintenance, repair, etc.

In other examples of this technology, however, the fourth facet 304 and/or the fifth facet 305 may provide structure to enable further expansion of the substrate processing capabilities of a substrate processing system. As shown in broken lines in FIGS. 2 and 3A, the fourth facet 304 and/or the fifth facet 305 may be equipped with at least one substrate transfer slot 252. The substrate transfer slot(s) 252, when present, may be sealed (e.g., by a removable seal plate) in substrate processing system 200 arrangements of the type shown in FIG. 2 where no substrate processing chamber 900 is attached to the fourth facet 304 and/or the fifth facet 305. The substrate transfer slot 252 in the fourth facet 304 and/or fifth facet 305 also may be smaller than corresponding slots in the other facets 301, 302, 303, 306, 607, 608, 609, 610, 611 (although it need not be in all examples of this technology).

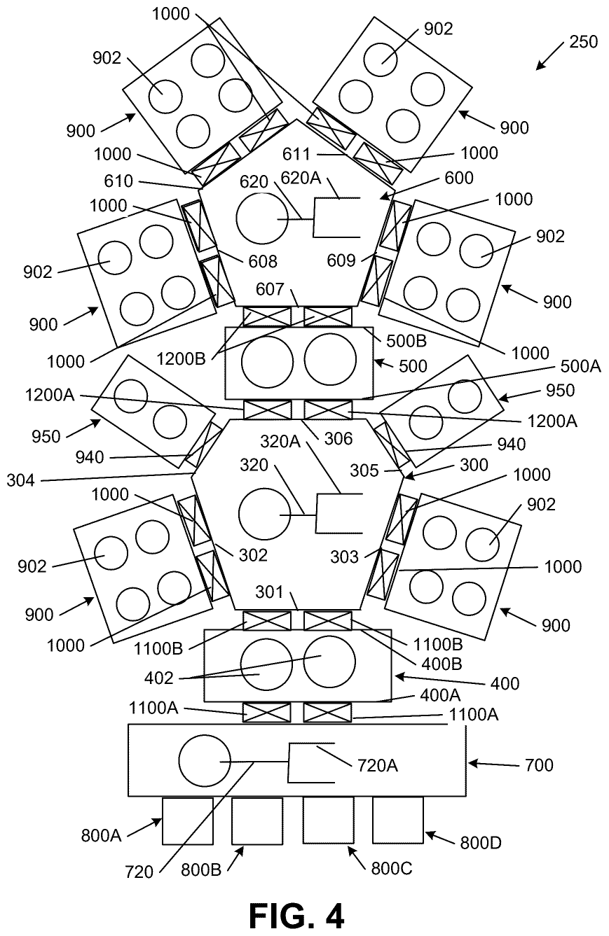

FIG. 4 provides a schematic view of another example substrate processing system 250 having further expanded processing capabilities utilizing the fourth facet 304 and/or fifth facet 305 in the manner described above. Where the same reference numbers are used in FIG. 4 as used in FIGS. 2-3C, the same or similar parts are being referenced, and much of the repetitive description may be omitted. As shown in FIG. 4, in this example substrate processing system 250, the fourth facet 304 is coupled with a substrate processing chamber 950 via one or more gate valves 940 and/or the fifth facet 305 is coupled with a substrate processing chamber 950 via one or more gate valves 940. The substrate processing chamber(s) 950 coupled with the fourth facet 304 and/or the fifth facet 305 may be made somewhat smaller (e.g., if the fourth facet 304 and/or the fifth facet 305 are smaller than other facets), as shown in FIG. 4. Alternatively, the substrate processing chamber(s) 950 may be sized, shaped, and/or equipped the same as any one or more of substrate processing chamber(s) 900. As another option, if desired, the fourth facet 304 and/or the fifth facet 305 may be sized, shaped, and equipped in the same manner as the second facet 302 and/or the third facet 303. Gate valve(s) 940 may have the same structure as any of gate valves 1000, 1100A, 1100B, 1200A, and/or 1200B, or they may have different structures.

FIG. 5 schematically illustrates an example load-lock module 400, 500 that may be used in accordance with some examples of this technology. Load-lock module 400 includes opposing faces 400A and 400B and load-lock module 500 includes opposing faces 500A and 500B (see also FIG. 4). Each of these opposing faces 400A, 400B, 500A, 500B has a plurality of (for example, four) substrate transfer ports 412, which in this example are arranged in a 2×2 matrix (two substrate transfer ports 412 for faces 400B, 500B are shown in broken lines in FIG. 5). When used as the first load-lock module 400: (a) face 400A may engage a four gate valve 1100A arrangement that sealingly couples face 400A and equipment front end module 700 and (b) face 400B may engage a four gate valve 1100B arrangement that sealingly couples face 400B and the first facet 301 of the first substrate handling chamber 300. When used as the second load-lock module 500: (a) face 500A may engage a four gate valve 1200A arrangement that sealingly couples face 500A and the sixth facet 306 of the first substrate handling chamber 300 and (b) face 500B may engage a four gate valve 1200B arrangement that sealingly couples face 500B and the seventh facet 607 of the second substrate handling chamber 600. Each of the equipment front end module 700, the first facet 301 of the first substrate handling chamber 300, the sixth facet 306 of the first substrate handling chamber 300, and the seventh facet 607 of the second substrate handling chamber 600 may include substrate transfer slots arranged in a 2×2 matrix that align with corresponding four substrate transfer ports 412 on faces 400A, 400B, 500A, 500B. Substrate transfer slots in a similar 2×2 matrix may be provided in one or more of the substrate processing chambers 900, the second facet 302, the third facet 303, the eighth facet 608, the ninth facet 609, the tenth facet 610, and the eleventh facet 611. As discussed above, some or all of the various components of the system 200 may have a common (e.g., identical) and/or modular connection structure for connecting with other components of the system 200. Such a connection structure is shown by way of example with connectors (e.g., bolt hardware) 450. Thus, for example, the first load-lock module 400 and the second load-lock module 500 may have the same connection structure with the same layout of connectors 450, and this connection structure (e.g., connectors 450 layout) may be included in the other components of the system 200 such as the first substrate handling chamber 300, the second substrate handling chamber 600, and/or the valves 1100A, 1100B, 1200A, 1200B between those components. While a particular number of the connectors 450 are shown in FIG. 5, it will be understood that a fewer or greater number of connectors 450 may be used. Moreover, while the connectors 450 are shown near a perimeter of the first load-lock module 400 and the second load-lock module 500, the connectors 450 may be located at any position(s) on the first load-lock module 400 and the second load-lock module 500. By placing the connectors 450 in the same locations for both the first load-lock module 400 and the second load-lock module 500, the first load-lock module 400 and the second load-lock module 500 may be interchangeable physically with each other within the system 200. That is, the first load-lock module 400 may be interchanged within the system 200 and connect in the same manner between their respective elements of the system 200. As part of such an interchange, it may be desirable to configure the first load-lock module 400 and/or the second load-lock module 500 to enable or disable one or more functions of the first load-lock module 400 and/or the second load-lock module 500. For example, it may be desired to enable or disable heating, cooling, or pressurization/depressurization for one or both of the first load-lock module 400 and/or the second load-lock module 500 as desired. Providing the same connector 450 configuration and at least some of the same functionalities between the first load-lock module 400 and the second load-lock module 500 so that they are interchangeable, may offer significant benefits for both maintenance and scalability. When parts are standardized and interchangeable, faulty or worn-out components (such as the load-lock modules 400, 500) may be quickly replaced without requiring specialized replacements, potentially reducing downtime and costs, and may potentially allow for more efficient and flexible configuration of the system. This flexibility may also streamline inventory management since fewer unique spare parts may be needed. In addition, system expansion may become simpler, as new load-lock modules may be added or swapped in without redesigning the entire architecture. This modularity may increase efficiency, improve reliability, and support future upgrades, making the system more adaptable to evolving needs while extending its overall lifespan through ease of replacement and expansion.

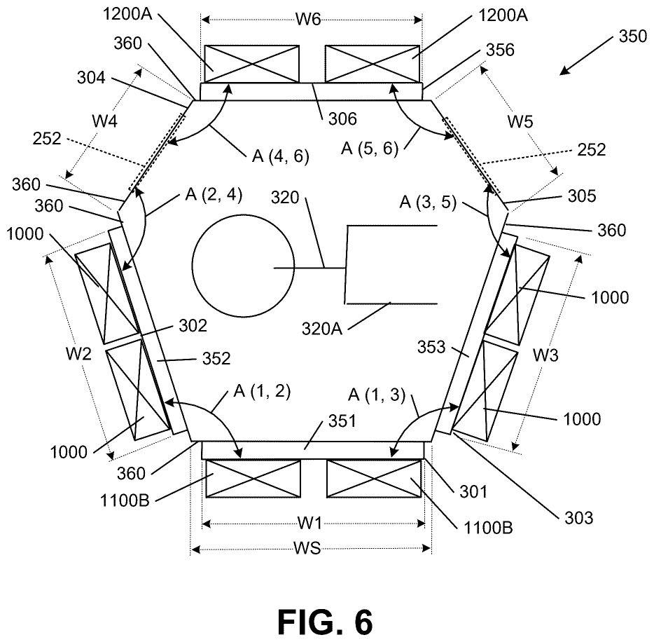

FIGS. 2-4 show the facets 301-306 and 607-611 as located flush with, corresponding to, and/or spanning the entire width of a corresponding side or face of substrate handling chambers 300, 600. But the facets 301-306 and 607-611 need not have those properties, e.g., as noted above, the facets 301-306 and 607-611 need not span the entire width (and/or height) of a side or face of a substrate handling chamber 300, 600. FIG. 6 illustrates an example. Where the same reference numbers are used in FIG. 6 as are used in FIGS. 2-5, the same or similar part is being referenced, and much of the overlapping description has been omitted.

FIG. 6 illustrates a substrate handling chamber 350 similar to that shown in FIG. 3A, but in the example of FIG. 6, the first facet 301, second facet 302, third facet 303, and sixth facet 306 are provided on projecting members 351, 352, 353, and 356, respectively, that extend outward from the main major sides or faces 360 of the substrate handling chamber 350. As shown in FIG. 6, the first facet 301, second facet 302, third facet 303, and sixth facet 306 do not extend the full width of its corresponding main major side or face 360 (e.g., width W1 of the facet 301 is less than width WS of the main major side or face 360 on which the projecting member 351 for the first facet 301 is provided). Similarly while they could, one or more of the projecting members 351, 352, 353, and/or 356 need not extend the entire vertical height of the substrate handling chamber 350's side or face 360. Rather, if desired, projecting members 351, 352, 353, and 356 including facets 301, 302, 303, and 306 may constitute outwardly extending components (e.g., mounting surfaces) located over only a portion of its respective main major side or face 360, e.g., configured to engage one or more gate valves 1000, 1100B, 1200A. The facets (e.g., at least 301, 302, 303, and 306) may include metal plates (e.g., aluminum or aluminum alloy) forming a surface for engaging a surface of one of the gate valves 1000, 1100B, 1200A.

The example substrate handling chamber 350 of FIG. 6, however, still includes: (a) a first facet 301, (b) a second facet 302 extending at an oblique angle A (1, 2) with respect to the first facet 301, (c) a third facet 303 extending at an oblique angle A (1, 3) with respect to the first facet 301, (d) a fourth facet 304 extending at an oblique angle A (2, 4) with respect to the second facet 302, (e) a fifth facet 305 extending at an oblique angle A (3, 5) with respect to the third facet 303, and (f) a sixth facet 306 connected between the fourth facet 304 and the fifth facet 305. Each of the angles A (4, 6) and A (5, 6) (the angle of the sixth facet 306 with respect to the fourth facet 304 and the angle of the sixth facet 306 with respect to the fifth face 305) also is an oblique angle. Further, in this specifically illustrated example, the first facet 301, the second facet 302, the third facet 303, and the sixth facet 306 are the same size and are larger than the fourth facet 304 and the fifth facet 305. The fourth facet 304 and fifth facet 305 also may be the same size. The facets 301, 302, 303, and 306 further may include one or more substrate transfer slots, as discussed above.

Similarly, one or more of the facets 607-611 of the second substrate handling chamber 600 may be provided on projecting members similar to projecting members 351, 352, 353, and 356. In this manner, one or more of the facets 607-611 of the second substrate handling chamber 600 may not span an entire width and/or vertical height of a main major side or face of the second substrate handling chamber 600 on which it is provided.

Returning to FIGS. 2-3B, some operational methods of substrate processing systems 200 (and 250) in accordance with aspects of this technology will be described below. First, a substrate for processing in substrate processing system 200, 250 will be loaded into the substrate processing system 200, 250 through one of the loading ports 800A-800D. Robotic arm 720 of the equipment front end module 700 picks up the substrate from its loading port 800A-800D and moves it into the interior chamber of the equipment front end module 700. The substrate can be held in the equipment front end module 700 for any desired time period.

To begin processing, one of gate valves 1100A is opened, the robotic arm 720 of the equipment front end module 700 picks up the substrate from its holding location in the equipment front end module 700 (if necessary), and the robotic arm 720 moves the substrate through the gate valve 1100A to a substrate support 402 in the first load-lock module 400. The robotic arm 720 is retracted back into the equipment front end module 700, and the gate valve 1100A is closed. The substrate can be held any desired amount of time on substrate support 402.

When scheduled for further processing, a gate valve 1100B may be opened. The substrate may be picked up from substrate support 402 in first load-lock module 400 by robotic arm 320 of the first substrate handling chamber 300 and moved into the interior of the first substrate handling chamber 300 through the first facet 301 of the first substrate handling chamber 300. The substrate can be held for any desired amount of time within first substrate handling chamber 300 (e.g., placed on a support within the substrate handling chamber 300, if needed).

From there, the substrate may be moved into one of the substrate processing chambers 900 coupled with the second facet 302 or the third facet 303. To do so, one of the gate valves 1000 is opened, and the robotic arm 320 moves the substrate from the substrate handling chamber 300 into one of the substrate processing chambers 900 through gate valve 1000 and places the substrate on substrate support 902. The robotic arm 320 then is retracted from the substrate processing chamber 900 and gate valve 1000 is closed. A first treatment process (e.g., a layer deposition process) occurs on the substrate while the substrate processing chamber 900 is sealed off from the substrate handling chamber 300 by gate valve 1000. In a similar manner, a substrate may be placed in substrate processing chamber 950 through a gate valve 940 coupled with the fourth facet 304 and/or the fifth facet 305 in substrate processing systems 250 that are equipped in that manner.

Once this processing step is complete, the substrate may be scheduled for further processing in another one of the substrate processing chambers 900, such as one connected to the second substrate handling chamber 600. In such methods, the substrate must be moved from the substrate processing chamber 900 in which it is contained to the second substrate handling chamber 600. To do so, the processing includes: (i) opening gate valve 1000 to the substrate processing chamber 900 including the substrate; (ii) picking up the substrate with robotic arm 320; (iii) moving the substrate from the substrate processing chamber 900 into the first substrate handling chamber 300; (iv) closing gate valve 1000; (v) opening gate valve 1200A; (vi) moving the substrate from the first substrate handling chamber 300 to the second load-lock module 500 through the sixth facet 306 and gate valve 1200A; (vii) placing the substrate on substrate support 502; (viii) retracting the robotic arm 320 back into the first substrate handling chamber 300; and (ix) closing the gate valve 1200A. If necessary, the substrate may be stored within the first substrate handling chamber 300 for a time period before it is transferred into the second load-lock module 500 and/or it may be stored in the second load-lock module 500 before it is transferred further into the second substrate handling chamber 600.

To further transfer the substrate into the second substrate handling chamber 600: (i) one of gate valves 1200B is opened; (ii) the robotic arm 620 extends through the opened gate valve 1200B and picks up the substrate; (iii) the robotic arm 620 moves the substrate into the second substrate handling chamber 600 through the seventh facet 607; and (iv) gate valve 1200B is closed. Then, a gate valve 1000 connecting one of the eighth facet 608, ninth facet 609, tenth facet 610, or eleventh facet 611 to the substrate processing chamber 900 will be opened, and the robotic arm 620 will move the substrate into the substrate processing chamber through the opened gate valve 1000. The robotic arm 620 then will be retracted through the gate valve 1000 and back into the second substrate handling chamber 600, and the gate valve 1000 will be closed. Another treatment process (e.g., another layer deposition process) occurs on the substrate while the substrate processing chamber 900 is sealed off from the substrate handling chamber 600 by gate valve 1000.

Once processing in that substrate processing chamber 900 is complete, the substrate then can be removed from the substrate processing system 200. This can be accomplished in the general manners described above by moving the substrate: (a) from the substrate processing chamber 900 coupled with one of facets 608, 609, 610, or 611, (b) into the second substrate handling chamber 600, (c) then into second load-lock module 500, (d) then into the first substrate handling chamber 300, (e) then into the first load-lock module 400, (f) then into the equipment front end module 700, and (g) then into one of the loading ports 800A-800D. The various gate valves 1000, 1200B, 1200A, 1100B, and 1100A will be opened and closed at appropriate times in the general manners described above to enable substrate transfer through the various components under proper pressure conditions and in appropriate atmospheric conditions.

The process described above includes processing the substrate in one substrate processing chamber 900 connected with the first substrate handling chamber 300 and in one substrate processing chamber 900 connected with the second substrate handling chamber 600. Many other options are possible in other examples of this technology. As one example, the substrate may be processed in more than one substrate processing chamber 900 coupled with the first substrate handling chamber 300 and/or in more than one substrate processing chamber 900 coupled with the second substrate handling chamber 600. As another example, for some substrates, processing may be needed only in one or more substrate processing chambers 900 coupled with the second substrate handling chamber 600. In that case, the substrate may simply “pass through” the first substrate handling chamber 300 (without going into an associated substrate processing chamber 900 coupled with the first substrate handling chamber 300) on its way to the second load-lock module 500 and second substrate handling chamber 600. As another example, a substrate may be processed in a substrate processing chamber 900 associated with the first substrate handling chamber 300 after it has already been processed in a substrate processing chamber 900 associated with the second substrate handling chamber 600. Additionally or alternatively, a single substrate could pass between the first substrate handling chamber 300 and the second substrate handling chamber 600 through the second load-lock module 500 multiple times in a processing method before being fully processed. In such a case, the second load-lock module 500 may function merely as a transfer chamber (e.g., a “pass through” chamber) between the first substrate handling chamber 300 and the second substrate handling chamber 600. The second load-lock module 500 may be used as a transfer chamber that performs no processing on the substrate other than mere handling when, for example, the first substrate handling chamber 300 and the second substrate handling chamber 600 are operated at the same pressure and the temperature. Where the second load-lock module 500 acts as a pass-through chamber (PTC), the second load-lock module 500 may be directly connected to the first substrate handling chamber 300 without the need for the valves 1200A and/or directly connected to the second substrate handling chamber 600 without the need for the valves 1200B.

In the processes described above, the first robotic arm 320 of the first substrate handling chamber 300 is capable of interacting with eac950h of: (a) the first load-lock module 400 engaged with the first facet 301 (through any of gate valves 1100B and engaging any substrate support 402 in first load-lock module 400); (b) the substrate processing chambers 900 engaged with the second facet 302 and third facet 303 (through any of the gate valves 1000 present and engaging any substrate support 902 present in the substrate processing chamber 900); (c) if present, the substrate processing chambers 950 engaged with the fourth facet 304 and/or fifth facet 305 (through any of the gate valves 940 present and engaging any substrate support present in the substrate processing chamber 950); and (d) the second load-lock module 500 engaged with the sixth facet 306 (through any of gate valves 1200A and engaging any substrate support 502 in second load-lock module 500).

At least the facets 301, 302, 303, 306, 607, 608, 609, 610, and/or 611; the gate valves 1000, 1100A, 1100B, 1200A, and/or 1200B; the load-lock modules 400 and/or 500; the substrate processing chambers 900 and/or 950; and/or the structures for connecting these components may have a common and/or modular type connection structure, e.g., to maximize interchangeability and modularity. The two load-lock modules 400/500 may have the same structures, components, and/or functionality, or they may have some differences (e.g., with just one load-lock module 400, 500 having chill plates and/or heaters, with neither load-lock module 400, 500 having chill plates and/or heaters; or with both load-lock modules 400, 500 having chill plates and/or heaters).

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A semiconductor processing system comprising:
a front end configured to receive a substrate;
a first substrate handling chamber;
a first load-lock module configured to pass the substrate between the front end and the first substrate handling chamber, the first load-lock module comprising:
a first connection structure configured to connect with the front end; and
a second connection structure configured to connect with the first substrate handling chamber;
a second substrate handling chamber; and
a second load-lock module configured to pass the substrate between the first substrate handling chamber and the second substrate handling chamber, the second load-lock module comprising:
a third connection structure, substantially the same as the first connection structure, configured to connect with the first substrate handling chamber; and
a fourth connection structure, substantially the same as the second connection structure, configured to connect with the second substrate handling chamber.

2. The semiconductor processing system of claim 1, wherein the first connection structure comprises a first configuration of connectors and the second connection structure comprises a second configuration of connectors.

3. The semiconductor processing system of claim 1, wherein the first load-lock module and the second load-lock module comprise one or both of:
the same components, or
the same structures.

4. The semiconductor processing system of claim 1, wherein the first load-lock module and the second load-lock module are interchangeable in the semiconductor processing system.

5. The semiconductor processing system of claim 1, wherein the first load-lock module and the second load-lock module have the same transfer port configuration.

6. The semiconductor processing system of claim 1, wherein:
the first load-lock module is configured to perform at least one of actively heating the substrate or actively cooling the substrate, and
the second load-lock module is configured to pass the substrate between the first substrate handling chamber and the second substrate handling chamber without actively heating the substrate and without actively cooling the substrate.

7. The semiconductor processing system of claim 1, wherein a facet of the first load-lock module facing the front end, and a facet of the second load-lock module facing the first substrate handling chamber, have edge-to-edge dimensions that are substantially equal to each other.

8. The semiconductor processing system of claim 1, wherein a facet of the first load-lock module facing the first substrate handling chamber, and a facet of the second load-lock module facing the second substrate handling chamber, have edge-to-edge dimensions that are substantially equal to each other.

9. The semiconductor processing system of claim 1, further comprising:
a first semiconductor processing chamber connected to the first substrate handling chamber and configured to perform a first treatment process on the substrate; and
a second semiconductor processing chamber connected to the second substrate handling chamber and configured to perform a second treatment process on the substrate.

10. A semiconductor processing system comprising:
a first substrate handling chamber;
a first load-lock module configured to pass the substrate between a front end and the first substrate handling chamber;
a second substrate handling chamber; and
a second load-lock module configured to pass the substrate between the first substrate handling chamber and the second substrate handling chamber,
wherein the first load-lock module and the second load-lock module are interchangeable in the semiconductor processing system.

11. The semiconductor processing system of claim 10, wherein the first load-lock module and the second load-lock module share substantially identical connection structures.

12. The semiconductor processing system of claim 10, wherein the first load-lock module and the second load-lock module comprise one or both of:
the same components, or
the same structures.

13. The semiconductor processing system of claim 10, wherein the first load-lock module and the second load-lock module have the same transfer port configuration.

14. The semiconductor processing system of claim 10, wherein:
the first load-lock module is configured to perform at least one of actively heating the substrate or actively cooling the substrate, and
the second load-lock module is configured to pass the substrate between the first substrate handling chamber and the second substrate handling chamber without actively heating the substrate and without actively cooling the substrate.

15. The semiconductor processing system of claim 10, wherein a facet of the first load-lock module facing the front end, and a facet of the second load-lock module facing the first substrate handling chamber, have edge-to-edge dimensions that are substantially equal to each other.

16. The semiconductor processing system of claim 10, wherein a facet of the first load-lock module facing the first substrate handling chamber, and a facet of the second load-lock module facing the second substrate handling chamber, have edge-to-edge dimensions that are substantially equal to each other.

17. The semiconductor processing system of claim 10, further comprising:
a first semiconductor processing chamber connected to the first substrate handling chamber and configured to perform a first treatment process on the substrate; and
a second semiconductor processing chamber connected to the second substrate handling chamber and configured to perform a second treatment process on the substrate.

18. A method performed using a semiconductor processing system, the method comprising:
moving a substrate from a first load-lock module into a first substrate handling chamber;
moving the substrate from the first substrate handling chamber into a first substrate processing module;
performing a first treatment process on the substrate in the first substrate processing module;
moving the substrate from the first substrate processing module into the first substrate handling chamber;
moving the substrate from the first substrate handling chamber into a second load-lock module;
moving the substrate from the second load-lock module into a second substrate handling chamber;
moving the substrate from the second substrate handling chamber into a second substrate processing module; and
performing a second treatment process on the substrate in the second substrate processing module,
wherein the first load-lock module and the second load-lock module are interchangeable in the semiconductor processing system.

19. The method of claim 18, wherein the first load-lock module and the second load-lock module share substantially identical connection structures.

20. The method of claim 19, wherein:
a facet of the first load-lock module facing a front end of the semiconductor processing system, and a facet of the second load-lock module facing the first substrate handling chamber, have edge-to-edge dimensions that are substantially equal to each other; and
a facet of the first load-lock module facing the first substrate handling chamber, and a facet of the second load-lock module facing the second substrate handling chamber, have edge-to-edge dimensions that are substantially equal to each other.
